(19) United States
(12) Patent Application Publication
(10) Pub. No.: US 2013/0015837 A1
(43) Pub. Date: Jan. 17, 2013

(54) ON-CHIP SIGNAL WAVEFORM MEASUREMENT CIRCUIT

(71) Applicants: Keith A. Jenkins, Sleepy Hollow, NY (US); Peter Z. Wang, Yorktown Heights, NY (US)

(72) Inventors: Keith A. Jenkins, Sleepy Hollow, NY (US); Peter Z. Wang, Yorktown Heights, NY (US)

(73) Assignee: INTERNATIONAL BUSINESS MACHINES CORPORATION, Armonk, NY (US)

(21) Appl. No.: 13/182,016

(22) Filed: Jul. 13, 2011

(51) Int. Cl. G01R 19/00

(52) U.S. Cl. 324/76.11

(57) ABSTRACT

Methods and apparatus are provided for on-chip signal waveform measurement. An integrated circuit is provided that comprises an on-chip comparator for comparing a voltage level of a signal to be measured to a voltage level of a reference voltage, at a time determined by at least one edge of an evaluation clock. The reference voltage can be varied to obtain a plurality of voltage points. The evaluation clock can be varied to obtain a plurality of time sampling points. In addition, the reference voltage and the evaluation clock can both be varied to obtain a plurality of voltage-time sampling points constituting a waveform corresponding to the signal to be measured.

### FIELD OF THE INVENTION

The present invention relates generally to signal measurement techniques, and, more particularly, to methods and apparatus for on-chip signal waveform measurement.

### BACKGROUND OF THE INVENTION

In the design, measurement, and operation of integrated circuits, it is often useful to have a measurement of the signals propagating through the circuit. For example, it may be necessary to measure signal delay, signal rise and fall time, and/or signal overshoot and undershoot. Currently, observations of such signals inside the circuit requires delivering those signals to an external test point on the circuit with high fidelity, and the measurement of such signals with high bandwidth test equipment, such as oscilloscopes or spectrum analyzers. In many cases, however, it is desired to measure the signals directly on the silicon, eliminating the need for test points and external equipment.

A need therefore exists for methods and apparatus for on-chip signal waveform measurement.

### SUMMARY OF THE INVENTION

Generally, methods and apparatus are provided for on-chip signal waveform measurement. According to one aspect of the invention, an integrated circuit is provided that comprises an on-chip comparator for comparing a voltage level of a signal to be measured to a voltage level of a reference voltage, at a time determined by at least one edge of an evaluation clock. The reference voltage can be varied to obtain a plurality of voltage points. The evaluation clock can be varied to obtain a plurality of time sampling points. In addition, the reference voltage and the evaluation clock can both be varied to obtain a plurality of voltage-time sampling points constituting a waveform corresponding to the signal to be measured. Need to mention that the signal to be measured must be repetitive (as on page 3 line 24)? Need to mention this in the abstract?

The evaluation clock can be derived from the signal to be measured. In addition, the evaluation clock can be delayed by a programmable delay generator in programmable steps during a measurement mode. The evaluation clock programmable delay generator can be configured as loop to make a ring oscillator in a calibration mode to determine an amount of delay added for each programmable step.

An exemplary reference voltage generator is provided that generates the reference voltage, wherein the reference voltage generator is comprised of a chain of resistors and one or more transmission gates. An exemplary calibration voltage generator is provided that generates a calibration voltage, wherein the calibration voltage generator is comprised of a chain of resistors and one or more transmission gates.

According to a further aspect of the invention, a duty cycle can be determined by maintaining the reference voltage at a predefined value and stepping through a plurality of delay settings.

A more complete understanding of the present invention, as well as further features and advantages of the present invention, will be obtained by reference to the following detailed description and drawings.

### BRIEF DESCRIPTION OF THE DRAWINGS

FIG. 1A illustrates an on-chip signal waveform measurement circuit incorporating aspects of the present invention;

FIGS. 1B and 1C illustrate a signal to be measured that is greater than and less than, respectively, a reference voltage at evaluation time;

FIG. 2 illustrates an exemplary implementation of an on-chip signal waveform measurement circuit incorporating aspects of the present invention;

FIG. 3A illustrates an exemplary implementation of the reference voltage generator of FIG. 2;

FIG. 3B illustrates an exemplary implementation of a calibration voltage generator;

FIG. 4 is a schematic diagram illustrating an exemplary implementation of the comparator of FIG. 1;

FIG. 5 illustrates an exemplary implementation of an on-chip signal waveform measurement circuit incorporating aspects of the present invention;

FIG. 6 illustrates an exemplary memory array for storing the output of the comparator of FIGS. 1A, 2 and 5;

FIG. 7 illustrates an exemplary alternative implementation of an on-chip signal waveform measurement circuit incorporating aspects of the present invention; and

FIG. 8 illustrates the signal to be measured, the reference voltage (Vref), the evaluation clock and the comparator output, during an exemplary amplitude mode, for various times.

### DETAILED DESCRIPTION OF PREFERRED EMBODIMENTS

The present invention provides a sub-circuit built onto an integrated circuit (IC), referred to herein as an on-chip signal waveform measurement circuit, to perform measurements that were previously obtained with an external oscilloscope. According to one aspect of the present invention, the measurements are converted by the disclosed on-chip signal waveform measurement circuit to digital signals that can be delivered off-chip at low speed, or stored in digital form on memory on the IC. Generally, the disclosed on-chip signal waveform measurement circuit works by digitizing the signal of interest by comparing the signal level with an adjustable threshold voltage, measured at a time that is varied with respect to the time of a known signal, such as the system clock that operates the integrated circuit. Thus, the disclosed on-chip signal waveform measurement circuit measures the voltage of a signal as a function of time, and thereby measures the signal waveform. The disclosed on-chip signal waveform measurement circuit can be used to measure any signal that is repetitive in nature.

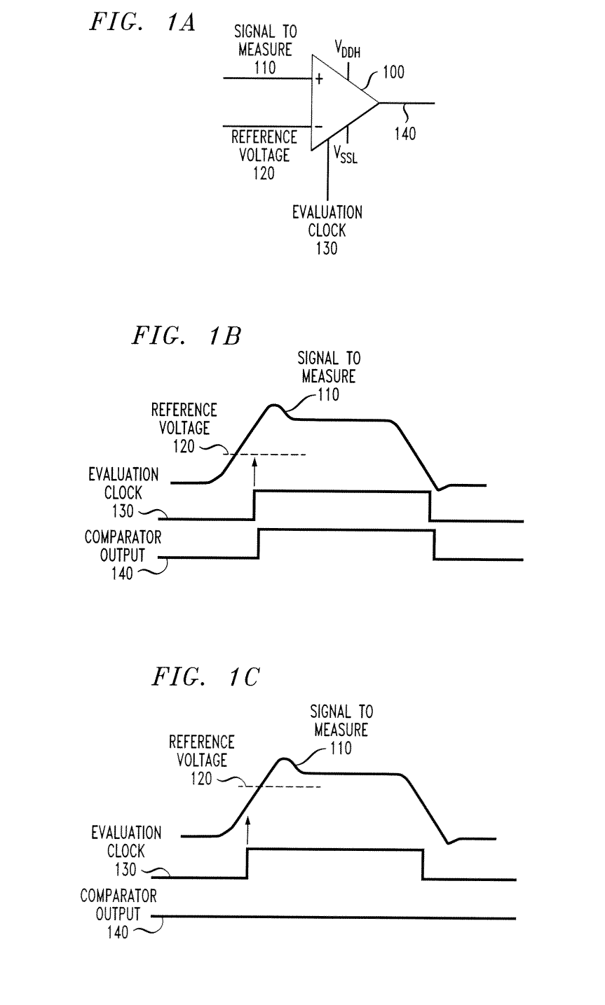

FIG. 1A illustrates an on-chip signal waveform measurement circuit 100 incorporating aspects of the present invention. As shown in FIG. 1A, the on-chip signal waveform measurement circuit 100 comprises a comparator circuit. The signal to be measured 110 is applied to a first input of the on-chip signal waveform measurement circuit 100. The voltage of this signal 110 is compared against a reference voltage 120 applied to a second input of the on-chip signal waveform measurement circuit 100. The comparison occurs at a time determined by a third input, an evaluation clock 130.

As shown in FIG. 1B, if the signal voltage 110 is greater than the reference voltage 120 at the time that the evaluation clock 130 goes high, for example, an output 140 of the comparator 100 indicates a positive output, or a logical “1.” As shown in FIG. 1C, if the signal voltage 110 is less than the reference voltage 120, the output 140 indicates a zero voltage, or a logical “0”. The output state is latched by the comparator 100 or a subsequent latch (not shown), and the state is held until the evaluation clock 130 is returned, for example, to a low state.

Thus, the comparator 100 determines if the voltage of the signal 110 to be measured is greater than a reference voltage 120 at a time determined by the edge of the evaluation clock 130. By adjusting the value of the reference voltage 120 and the time of the evaluation clock 130, a series of voltage-time points can be generated, and such points constitute a measurement of the waveform of the signal 110 to be measured.

As shown in FIG. 1A, the comparator 100 is operated from power supply levels, Vddh and Vssl, that are higher and lower, respectively, than the Vdd and Vss (e.g., ground) of the rest of the integrated circuit on which the on-chip signal waveform measurement circuit 100 resides. In this manner, signals that may rise above Vdd (overshoot) or fall below ground (undershoot) can be measured.

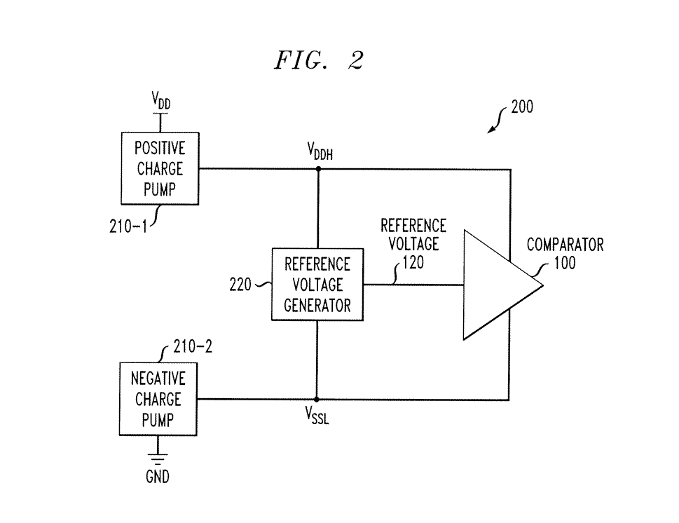

FIG. 2 illustrates an exemplary implementation of an on-chip signal waveform measurement circuit 200 incorporating aspects of the present invention. As shown in FIG. 2, the exemplary on-chip signal waveform measurement circuit 200 comprises a pair of charge pumps 210-1, 210-2 that generate the power supply levels, Vddh and Vssl, that operate the on-chip signal waveform measurement circuit 100. A positive charge pump 210-1 is connected to Vdd and generates the power supply level, Vddh. A negative charge pump 210-2 is connected to ground and generates the power supply level, Vssl. In a further variation, the power supply levels, Vddh and Vssl, can be achieved using off-chip power supplies.

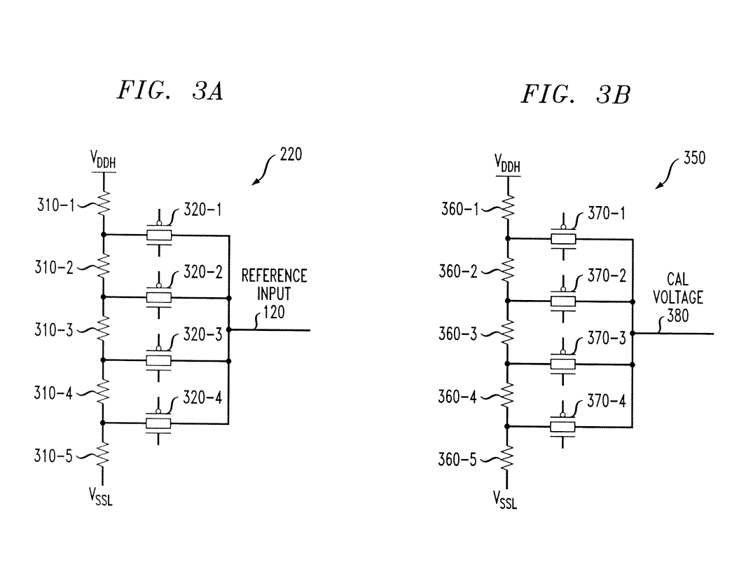

As shown in FIG. 2, the power supply levels, Vddh and Vssl, are also used as inputs to a reference voltage generator 220 that generates the reference voltage 120. An exemplary implementation of the reference voltage generator 220 is discussed further below in conjunction with FIG. 3A.

FIG. 3A illustrates an exemplary implementation of the reference voltage generator 220 of FIG. 2. As shown in FIG. 3A, the reference voltage generator 220 uses the power supply levels, Vddh and Vssl, available for the comparator 100 and comprises a chain of resistors 310-1 through 310-N (N=5 in the exemplary embodiment). Transmission gates 320-1 through 320-N−1 select a tap point on resistor chain 310 with a corresponding voltage to be used as the reference voltage input 120.

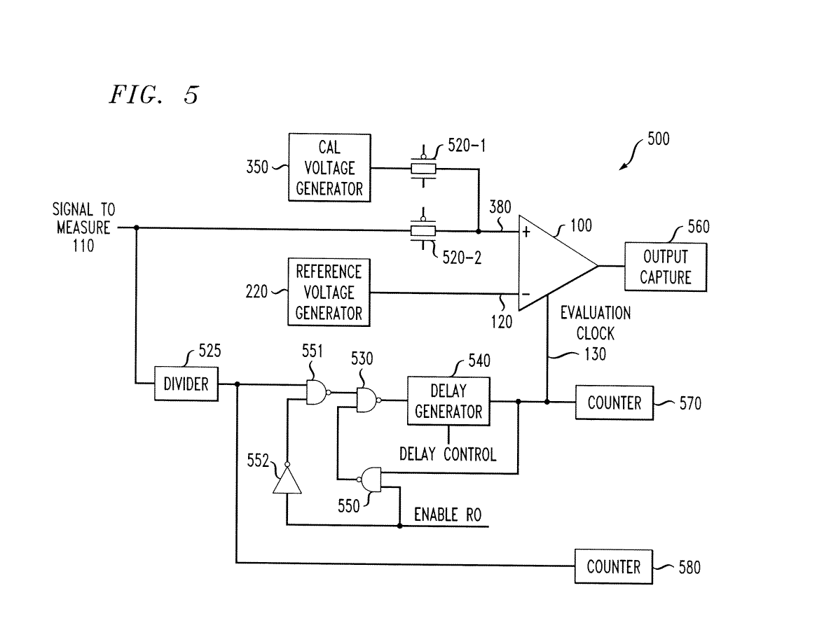

FIG. 3B illustrates an exemplary implementation of a calibration voltage generator 350 that is discussed further below in conjunction with FIG. 5. As shown in FIG. 3B, the calibration voltage generator 350 uses the power supply levels, Vddh and Vssl, available for the comparator 100 and comprises a chain of resistors 360-1 through 360-N (N=5 in the exemplary embodiment). Transmission gates 370-1 through 370-N−1 select a tap point on resistor chain 360 with a corresponding voltage to be used as the calibration voltage 380.

By selecting suitable calibration voltages 380 and reference voltages 120, using the generators 220, 350 of FIGS. 3A and 3B, respectively, any input voltage offset of the comparator 100 can be detected.

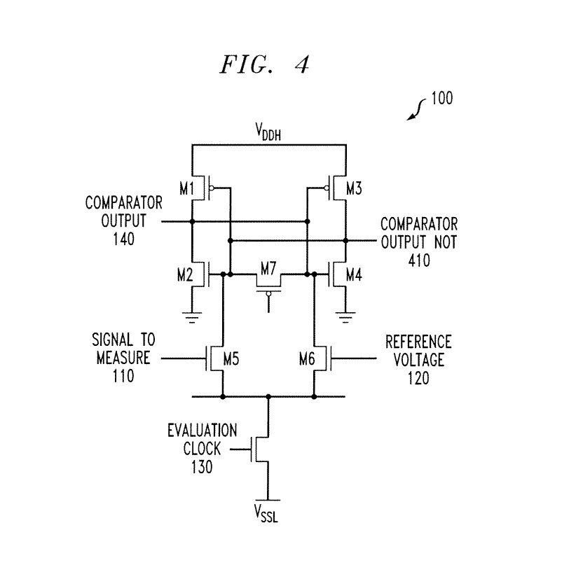

FIG. 4 is a schematic diagram illustrating an exemplary implementation of the comparator 100 of FIG. 1. Generally, the exemplary comparator 100 shown in FIG. 4 will resolve to a value of logic one on the output (and a logic zero on the out_not), if the signal to be measured 110 is at a lower voltage than the reference voltage 120; and will resolve to a value of logic zero on the output (and a logic one on the out_not), if the signal to be measured 110 is at a higher voltage than the reference voltage 120. In this manner, the exemplary comparator 100 shown in FIG. 4 determines if the signal 110 is higher or lower than the reference voltage at the time that the switch opens (based on the evaluation clock 130.

As shown in FIG. 4, the exemplary comparator 100 is comprised of a number of transistors M1 through M7. Transistors M1 through M4 form a pair of cross-coupled inverters, in a well-known manner. The outputs of transistors M1 through M4 are shorted together when the evaluation clock 130 is low, i.e., the pFET transistor M6 is on. When the evaluation clock 130 goes high, transistor M5 turns off, so the inverters can latch a state that depends on the voltages determined by transistors M5 and M6 (based on the relative values of the signal to be measured 110 and the reference voltage 120). The evaluation clock 130 also connects transistors M5 and M6 to V_{SSL} so they become biased and active. If the gate voltage on transistor M5 is greater than the gate voltage on transistor M6, transistor M5 will have a lower resistance to V_{SSL} than transistor M6, so the voltage on the gate of the inverter formed by transistors M2 and M3 will be lower than the gate voltage on the inverter formed by transistors M4 and M5, causing the inverters to latch a high value (a “1”) in the comparator out node. When the evaluation clock 130 goes low again, the latch is reset.

As discussed further below, the comparator 100 shown in FIG. 4 can be used to measure either 1) full waveforms (including undershoot and overshoot); 2) waveform amplitude (peak-to peak voltage values with no timing information); or 3) waveform duty cycle, according to the timing of the evaluation clock 130.

Full Waveform Measurements

FIG. 5 illustrates an exemplary implementation of an on-chip signal waveform measurement circuit 500 incorporating aspects of the present invention. As shown in FIG. 5, the exemplary on-chip signal waveform measurement circuit 500 comprises the reference voltage generator 220 and calibration voltage generator 350 of FIGS. 3A and 3B, respectively. The calibration voltage 380 generated by the calibration voltage generator 350 can optionally serve to verify the operation of the comparator 100 and specifically, measure any input offset voltage between the reference voltage 120 and the signal to be measured 110.

Transmission gates 520-1, 520-2 selectively apply either the calibration voltage 380 generated by the calibration voltage generator 350, or the signal to be measured 110 to a first input of the comparator 100. As discussed above in conjunction with FIG. 1, the reference voltage 120 is applied to a second input of the comparator 100.

An output capture element 560 can capture the output of the comparator 100. The output capture element 560 indicates whether the signal to be measured 110 is larger than the reference voltage 120 when the evaluation clock 130 arrives at the comparator 100. A number of exemplary techniques can be employed to record the output of the comparator 100:
latched logic state: captures a single change of the comparator output. The output goes into a “sticky” latch, that holds its value regardless of any input, until it is cleared by a reset signal.
majority vote logic state: a means to test the comparator state for several cycles, to see if, for example, m times out of n, the comparator 100 registers a high level. This is useful when the signal to be measured 110 has timing jitter so that some number of the evaluations may have a different value from the rest. The result is a single bit indicating whether the comparator 100 has indicated a transition.
average DC voltage: a means to use voltage measurement, rather than logic state, to determine the comparator output level. The comparator output is filtered by an on-chip RC filter (not shown in FIG. 5), such that hundreds or more cycles are averaged to a DC level, that can be measured on-chip or sent to a chip output. This DC voltage will not swing, in general, from 0 to Vdd, but between values determined by the duty cycle of the evaluation clock 130. Averaging in this manner also accommodates timing variation due to jitter.
an on-chip counter: the digital analog of an average DC voltage. The output of the comparator 100 is counted by an on-chip counter (not shown in FIG. 5). At the end of some period, the content of the counter can be compared to the number of signal cycles that have been evaluated. Equal or nearly equal number of counts indicates that the comparator 100 registered a “high” during that measurement interval. Such counting also accommodates timing variation due to jitter. The counts can be shifted off-chip, or compared on-chip to result in a single bit measurement.

In the exemplary full waveform measurement mode, the evaluation clock 130 is derived from the signal to be measured 110, as shown in FIG. 5. The frequency of the signal to be measured 110 may be divided, if necessary, using a divider 525. For example, if the comparator 100 requires a long recovery time after evaluating, the frequency of the signal to be measured 110 may be divided. The evaluation clock 130 is delayed with respect to the signal to be measured 110, so that the comparator 100 is operated at a time determined by this delay. A programmable delay generator 540, under control of a delay control signal, delays the evaluation clock 130 according to some digital code that is set, for example, by a finite state machine, or a scan chain. The value of the delay thus generated by the delay generator 540 can be calibrated by operating the delay generator 540 in a loop, as shown in FIG. 5, and measuring the frequency of the delay generator 540 using on-chip counters 570, 580.

The programmable delay generator 540 adds delay to the evaluation clock 130 in programmable steps which are controlled, for example, by a finite state machine, during the measurement operation. Calibration of the programmable delay generator 540 is required to determine how much delay is added per programmable step. Calibration is done by configuring the loop that generates the evaluation clock 130 as a ring oscillator, and measuring the frequency at each of the steps. Subtracting the inverse of frequency at one step from the inverse of the frequency at another step indicates the time delay between those two steps.

As shown in FIG. 5, the exemplary loop that generates the evaluation clock 130 also comprises three NAND gates 530, 550, 551 and an inverter 552 to configure the programmable delay generator 540 as an oscillator whose frequency is measured by counter 570 compared to the known signal frequency measured in counter 580. When the signal enable ro (need to assign this a number here and in the figure?) is low, the signal levels out of NAND gate 550 and inverter 552 are high, so NAND gates 551 and 530 transmit the signal to be measured 110 to the programmable delay generator 540. When enable ro signal is high, the output of inverter 551 is low, so the signal to measure 110 is blocked by NAND gate 551, but the NAND gate 530, delay generator 540 and NAND gate 550 form an inverting loop whose frequency depends on the delay through the delay generator 540, as required for calibration.

In the full waveform measurement mode, the waveform of the signal to be measured 110 is determined by changing both the reference voltage 120 and the timing of the evaluation clock 130, in either order. For example, at a fixed evaluation clock delay with respect to the signal 110, the reference voltage 120 can be swept from a low to a high value until the comparator 100 indicates that the signal 110 is greater than the reference voltage 120. This marks a voltage-time point on a waveform. The evaluation clock delay can then be changed, and the process repeated until a second voltage-time point is registered, and so on, until a full waveform is obtained.

The result of the comparator evaluation at each delay setting can be stored in an on-chip memory, such as the output capture element 560, until the full measurement sequence has been executed, or shifted off-chip after each evaluation.

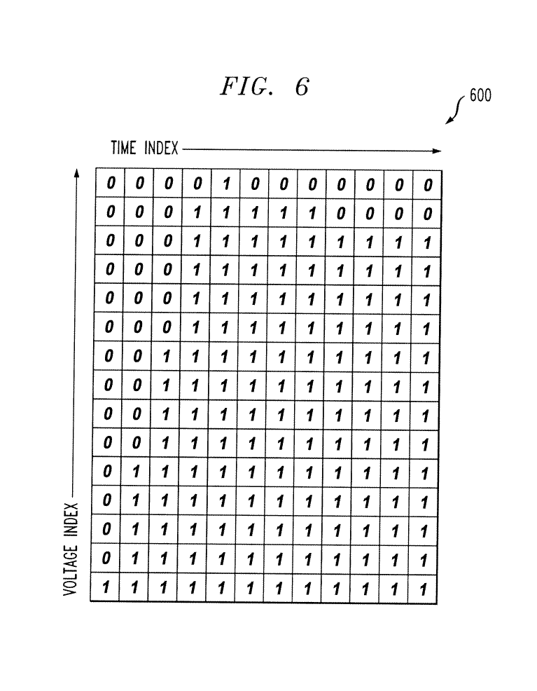

FIG. 6 illustrates an exemplary memory array 600 for storing the output of the comparator 100. In the exemplary embodiment of FIG. 6, the exemplary memory array 600 contains an element for each delay and reference voltage setting. The delay generator 540 of FIG. 5 generates the time index (identifying each column in the exemplary array 600) and the reference voltage generator 220 generates the voltage index (identifying each row in the exemplary array 600). The delay generator 540 and the reference voltage generator 220 can optionally be under the control of a finite state machine (FSM), not shown in FIG. 6.

Duty Cycle Measurement—Method 1

If the reference voltage 120 is set to Vdd/2, and not adjusted, for each setting of the evaluation clock delay, the comparator 100 will indicate if the signal to be measured 110 is greater than or less than Vdd/2. By stepping through the various delay settings, the output of the circuit thereby indicates how often the signal to be measured 110 is in a “high” state and how often it is in a “low” state. In other words, such an arrangement measures duty cycle of the signal to be measured 110.

Amplitude Measurement

In an exemplary amplitude mode, the evaluation clock 130 can be operated at a lower, asynchronous, frequency than that of the signal to be measured 110. The evaluation clock 130 can be generated on-chip in any known manner, or provided by an off-chip instrument.

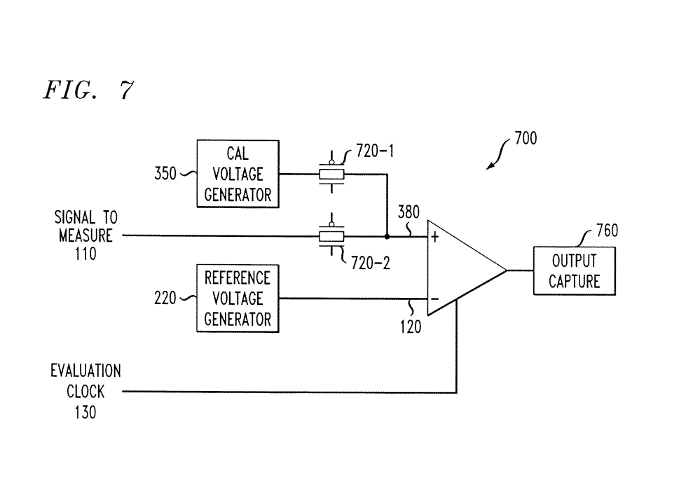

FIG. 7 illustrates an exemplary alternative implementation of an on-chip signal waveform measurement circuit 700 incorporating aspects of the present invention. As shown in FIG. 7, the exemplary on-chip signal waveform measurement circuit 700 comprises the reference voltage generator 220 and calibration voltage generator 350 of FIGS. 3A and 3B, respectively. The calibration voltage 380 generated by the calibration voltage generator 350 can optionally serve to verify the operation of the comparator 100 and specifically, measure any input offset voltage between the reference voltage 120 and the signal to be measured 110. Transmission gates 720-1, 720-2 selectively apply either the calibration voltage 380 generated by the calibration voltage generator 350, or the signal to be measured 110 to a first input of the comparator 100. As discussed above in conjunction with FIG. 1, the reference voltage 120 is applied to a second input of the comparator 100. An output capture element 760 can capture the output of the comparator 100, in a similar manner to FIG. 5.

It is noted that in an exemplary amplitude mode, the delay generator 540 of FIG. 5 is not required. In the exemplary amplitude mode, the comparator 100 is evaluated across the entire waveform asynchronously, and for each evaluation, registers if the signal 110 is above or below the reference voltage 120.

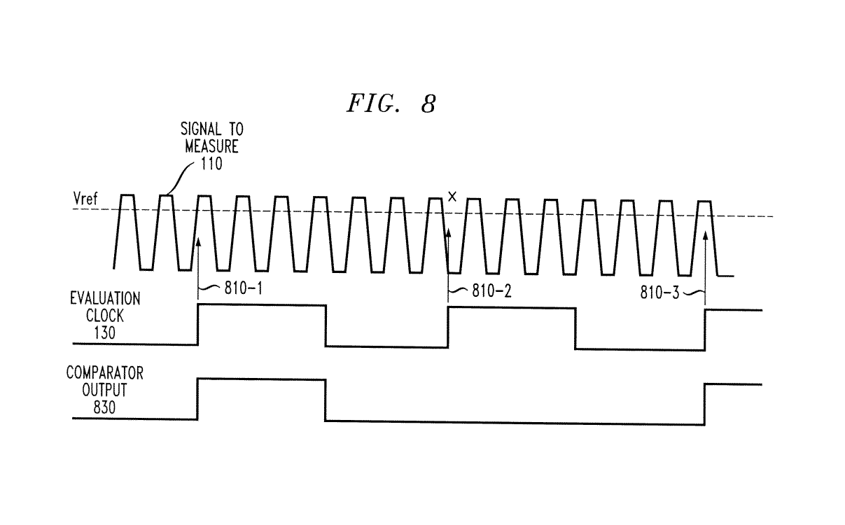

FIG. 8 illustrates the signal to be measured 110, the reference voltage 120 (Vref), the evaluation clock 130 and the comparator output 830, during an exemplary amplitude mode, for various times 810-1 through 810-3. As shown in FIG. 8, if the reference voltage 120 has a value somewhere between the minimum and maximum values of the signal to be measured 110, the comparator output 830 will sometimes be high and sometimes be low, according to the timing of the evaluation clock 130. However, if the reference voltage 120 is greater than the highest value of the signal to be measured 110, the comparator 100 will be at a low value. If the reference voltage 120 is lower than the lowest value of the signal to be measured 110, the comparator output will be of the same logical state as the evaluation clock 130. Thus, by stepping the reference voltage 120 over all possible values, the output capture circuit 560, 760 can determine the minimum and maximum values of the signal to be measured 110.

As this measurement does not use a synchronous evaluation clock, the output capture must use either average DC voltage or counter methods, as described above.

Duty Cycle Measurement—Method 2

If the reference voltage 120 is set to Vdd/2, and not adjusted, the amplitude measurement method can be used to measure duty cycle, as the amplitude measurement method determines, by asynchronous sample, how often the signal to measure is above the reference voltage 120, and how often below the reference voltage 120. If the average DC voltage output is used, the duty cycle can be expressed as follows:

Duty Cycle=Vo/Vdc/DCe (1)

where Vo is the measured DC voltage, and DCe is the duty cycle of the evaluation clock 130.

If the counter method is used, the duty cycle can be expressed as follows:

Duty Cycle=(comparator counts)/(total eval clock count) (2)

The foregoing description discloses only exemplary embodiments of the invention. Modifications of the above disclosed structures and method which fall within the scope of the invention will be readily apparent to those of ordinary skill in the art. Accordingly, while the present invention has been disclosed in connection with exemplary embodiments thereof, it should be understood that other embodiments may fall within the spirit and scope of the invention, as defined by the following claims.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An integrated circuit, comprising:
an on-chip comparator for comparing a voltage level of a signal to be measured to a voltage level of a reference voltage, at a time determined by at least one edge of an evaluation clock.

2. The integrated circuit of claim 1, wherein said reference voltage is varied to obtain a plurality of voltage points.

3. The integrated circuit of claim 1, wherein said evaluation clock is varied to obtain a plurality of time sampling points.

4. The integrated circuit of claim 1, wherein said reference voltage and said evaluation clock are varied to obtain a plurality of voltage-time sampling points constituting a waveform corresponding to said signal to be measured.

5. The integrated circuit of claim 1, wherein said evaluation clock is derived from said signal to be measured.

6. The integrated circuit of claim 1, further comprising a programmable delay generator to delay said evaluation clock in programmable steps during a measurement mode.

7. The integrated circuit of claim 6, further comprising a loop to generate said evaluation clock, and wherein said loop is configured as a ring oscillator in a calibration mode to determine an amount of delay added for each programmable step.

8. The integrated circuit of claim 1, wherein said comparator is operated from power supply levels, Vddh and Vssl, that are higher and lower, respectively, than power supply levels, Vdd and Vss, of a remainder of said integrated circuit.

9. The integrated circuit of claim 8, further comprising one or more charge pumps for generating power supply levels, Vddh and Vssl, to operate said comparator.

10. The integrated circuit of claim 1, further comprising a reference voltage generator that generates said reference voltage, wherein said reference voltage generator is comprised of a chain of resistors and one or more transmission gates.

11. The integrated circuit of claim 1, further comprising a calibration voltage generator that generates a calibration voltage, wherein said calibration voltage generator is comprised of a chain of resistors and one or more transmission gates.

12. The integrated circuit of claim 1, wherein an output of said comparator is obtained using one or more of a latched logic state, a majority vote logic state, an average DC voltage or an on-chip counter.

13. The integrated circuit of claim 1, wherein a duty cycle is determined by maintaining said reference voltage at a predefined value and stepping through a plurality of delay settings.

14. A method for measuring a signal on an integrated circuit, comprising:
applying a signal to be measured to an on-chip comparator on said integrated circuit; and
comparing a voltage level of said signal to be measured to a voltage level of a reference voltage using said on-chip comparator, at a time determined by at least one edge of an evaluation clock.

15. The method of claim 14, further comprising the step of varying said reference voltage to obtain a plurality of voltage points.

16. The method of claim 14, further comprising the step of varying said evaluation clock varied to obtain a plurality of time sampling points.

17. The method of claim 14, further comprising the step of varying said reference voltage and said evaluation clock to obtain a plurality of voltage-time sampling points constituting a waveform corresponding to said signal to be measured.

18. The method of claim 14, further comprising the step of deriving said evaluation clock from said signal to be measured.

19. The method of claim 14, further comprising the step of delaying said evaluation clock delayed using a programmable delay generator in programmable steps during a measurement mode.

20. The method of claim 19, further comprising the step of configuring a loop that generates said evaluation clock as a ring oscillator in a calibration mode to determine an amount of delay added for each programmable step.

21. The method of claim 14, further comprising the step of operating said comparator from power supply levels, Vddh and Vssl, that are higher and lower, respectively, than power supply levels, Vdd and Vss, of a remainder of said integrated circuit.

22. The method of claim 14, further comprising the step of obtaining an output of said comparator using one or more of a latched logic state, a majority vote logic state, an average DC voltage or an on-chip counter.

23. The method of claim 14, further comprising the step of determining a duty cycle by maintaining said reference voltage at a predefined value and stepping through a plurality of delay settings.

24. An on-chip comparator, comprising:
means for applying a signal to be measured to an on-chip comparator on said integrated circuit; and means for comparing a voltage level of said signal to be measured to a voltage level of a reference voltage, at a time determined by at least one edge of an evaluation clock.
